(19) United States
(12) Patent Application Publication
(10) Pub. No.: US 2025/0285261 A1
(43) Pub. Date: Sep. 11, 2025

(54) SAMPLE OBSERVATION METHOD

(71) Applicant: Hitachi High-Tech Corporation, Tokyo (JP)

(72) Inventors: Akira ITO, Tokyo (JP); Atsushi MIYAMOTO, Tokyo (JP); Naoaki KONDO, Tokyo (JP); Hirohiko KITSUKI, Tokyo (JP)

(73) Assignee: Hitachi High-Tech Corporation, Tokyo (JP)

(21) Appl. No.: 18/860,358

(22) PCT Filed: Jun. 10, 2022
(86) PCT No.: PCT/JP2022/023459

§ 371 Date: Oct. 25, 2024

(51) Int. Cl. G06T 7/00

(52) U.S. Cl. CPC G06T 7/001; G06T 2207/20081; G06T 2207/20084; G06T 2207/30148

(57) ABSTRACT

A method and device for observing a sample, includes acquiring a first learning image and a second learning image corresponding to the first learning image., Estimation processing parameters for an estimation engine for estimating the second learning image from the first learning image are learned using the first learning image and the second learning image, an estimated image estimated from the first learning image and the second learning image corresponding to the first learning image are divided into areas Ri (i=1 to N, and N is the number of areas) during learning of the estimation processing parameters, and the loss of pixel groups Pi from the second learning image and pixels groups Qi from the estimated image which are included in each of the areas Ri is learned using a loss function Fi for performing evaluation by means of a predetermined standard.

### TECHNICAL FIELD

The present invention relates to a method for acquiring an image for observing a sample by capturing an image of the sample such as a semiconductor wafer by using a charged particle microscope or the like, and relates to a method for estimating a higher quality image from the captured image. The invention includes a method for estimating images with different image qualities in accordance with regions in a case of learning a correspondence between a first learning image and a second learning image in advance using a machine learning method.

### BACKGROUND ART

In the manufacturing of semiconductor wafers, it is important to quickly start a manufacturing process and quickly transition to a high-yield mass production system in order to ensure profits. For this purpose, various kinds of inspection apparatuses, observation apparatuses, and measurement apparatuses have been applied to the manufacturing line.

A sample observation apparatus is an apparatus that captures high-resolution images at defect positions on a wafer on the basis of defect position coordinates (coordinate information indicating positions of defects on a sample) which are output by an inspection apparatus and outputs the images. Sample observation apparatuses (hereinafter referred to as review SEM) using a scanning electron microscope (SEM) are widely used. In semiconductor mass production lines, automation of observation work is desired. Thus, the review SEMs are equipped with a function for performing automatic defect review (ADR) processing that automatically collects images at defect positions on a sample.

There are multiple types of circuit pattern structures formed on semiconductor wafers, and there are also various types and locations of defects that occur. Thus, it is important to capture and output high-quality images with high visibility of defects and circuit patterns. Therefore, images for observing a sample are acquired by applying image processing techniques to raw captured images, which are formed by signals obtained from a detector of the review SEM, to improve visibility of the raw captured images. As methods for improving visibility, a number of methods have been proposed to learn the correspondence between images with different image qualities in advance and to estimate, in a case where an image with an image quality similar to one of the image qualities is input, an image with the other of the image qualities. For example, JP2018-137275A (PTL 1) describes a method of estimating a high-magnification image from a low-magnification image by learning a relationship between an image captured at a low magnification and an image captured at a high magnification in advance.

### CITATION LIST

### Patent Literature

PTL 1: JP2018-137275A

### Non-Patent Literature

NPL 1: Dong, Chao, et al. “Image super-resolution using deep convolutional networks.” arXiv preprint arXiv: 1501.00092 (2014).

### SUMMARY OF INVENTION

### Technical Problem

In the sample observation apparatus, it is important to output images with high visibility for observing defects, circuit patterns, and the like, and image processing is applied to the captured images to improve the visibility of the images. One method for this is a method of estimating a high-quality image from an input of a captured image by learning a relationship between the captured image and the high-quality image in advance through the machine learning method. In general, in the machine learning method, the loss between an estimated image and a high-quality image is calculated using a single loss function defined in advance, and an estimation processing parameter is updated to reduce the loss. However, since different observers want to observe different regions during observation, an image quality required for each region may differ. In such a case, it is difficult to perform learning such that images with different image qualities are estimated for respective regions by a single loss function.

### Solution to Problem

In order to solve the above-mentioned problem, according to an embodiment of the invention, there are provided an appearance inspection method having the following characteristics.

In a sample observation method,

a first learning image and a second learning image corresponding to the first learning image are acquired,

an estimation processing parameter of an estimation engine that estimates the second learning image from the first learning image is learned using the first learning image and the second learning image,

an estimated image, which is estimated from the first learning image, and the second learning image corresponding to the first learning image are divided into regions Ri (i=1 to N, where N is the number of regions), in learning of the estimation processing parameter, and

the learning is performed using a loss function Fi of evaluating a loss between a pixel group Pi of the second learning image and a pixel group Qi of the estimated image included in each region Ri on the basis of a predetermined criterion. Advantageous Effects of Invention

According to the embodiment of the invention, it is possible to change a method of calculating the loss in the learning of the estimation engine for each region, thereby improving performance of the image estimation engine.

### BRIEF DESCRIPTION OF DRAWINGS

FIG. 1 is a diagram illustrating an embodiment of a learning processing sequence of an estimation engine according to the invention.

FIG. 2 is a diagram for explaining the details of region division processing of the present embodiment illustrated in FIG. 1.

FIG. 3 is a diagram illustrating an example of an image of a three-layer circuit pattern according to a first embodiment.

FIG. 4 is a diagram illustrating division of an estimated image corresponding to a first learning image and a second learning image into a defective region R1″ and a non-defective region R2″, and learning of an estimation processing parameter using a loss function F1″ for R1″ and a loss function F2″ for R2″, according to the first embodiment.

FIG. 5 is a diagram illustrating a configuration for acquiring labeled images by assigning labels to patterns and background portions through layout information acquired from design data, according to the first embodiment.

FIG. 6 is a diagram illustrating a loss function Fi according to the first embodiment. The loss function Fi is defined as a weighted sum of element losses calculated using a plurality of element loss functions fij (j=1 to M, where M is the number of element losses), and a weight wij of an element loss value is changed for each region Ri of the second learning image.

FIG. 7 is a diagram illustrating an example of a graphical user interface (GUI) according to the present embodiment.

FIG. 8 is a diagram illustrating an example of a neural network having a three-layer structure according to the present embodiment.

FIG. 9 is a diagram illustrating the first learning image captured in a case where the number of frames added is 1 and the second learning image captured in a case where the number of frames added is 64, according to the present embodiment.

### DESCRIPTION OF EMBODIMENTS

Hereinafter, embodiments for carrying out the invention will be described, with reference to the drawings. It should be noted that the embodiments described below do not limit the invention according to the claims, and all of the elements described in the embodiments and their combinations may not be necessary for the solution of the invention.

### First Embodiment

The present embodiment is an embodiment of a sample observation method. In the sample observation method, a first learning image and a second learning image corresponding to the first learning image are acquired, an estimation processing parameter of an estimation engine that estimates the second learning image from the first learning image is learned using the first learning image and the second learning image, an estimated image, which is estimated from the first learning image, and the second learning image corresponding to the first learning image are divided into regions Ri (i=1 to N, where N is the number of regions), in learning of the estimation processing parameter, and the learning is performed using a loss function Fi of evaluating a loss between a pixel group Pi of the second learning image and a pixel group Qi of the estimated image included in each region Ri on the basis of a predetermined criterion.

(1)

That is, the first embodiment is an embodiment having the following configuration.

The first learning image and the second learning image corresponding to the first learning image are acquired,

the estimation processing parameter of the estimation engine that estimates the second learning image from the first learning image is learned using the first learning image and the second learning image,

the estimated image, which is estimated from the first learning image, and the second learning image corresponding to the first learning image are divided into the regions Ri (i=1 to N, where N is the number of regions), in the learning of the estimation processing parameter, and

the learning is performed using the loss function Fi of evaluating the loss between the pixel group Pi of the second learning image and the pixel group Qi of the estimated image included in each region Ri on the basis of the predetermined criterion.

A supplementary description of these features will be given. The estimation engine updates the estimation parameter on the basis of the loss. Therefore, the image quality of the image, which is output by the estimation engine after the learning, changes depending on the loss function used during the learning. In the related art, a single loss function is applied to the entire image, and the parameter of the estimation engine is learned. Therefore, it is difficult to perform learning such that images with different image qualities are estimated in accordance with regions. In the present embodiment, it is possible to estimate an image with a different image quality for each region by changing the loss function for each region.

Hereinafter, the features according to the present embodiment will be described in more detail.

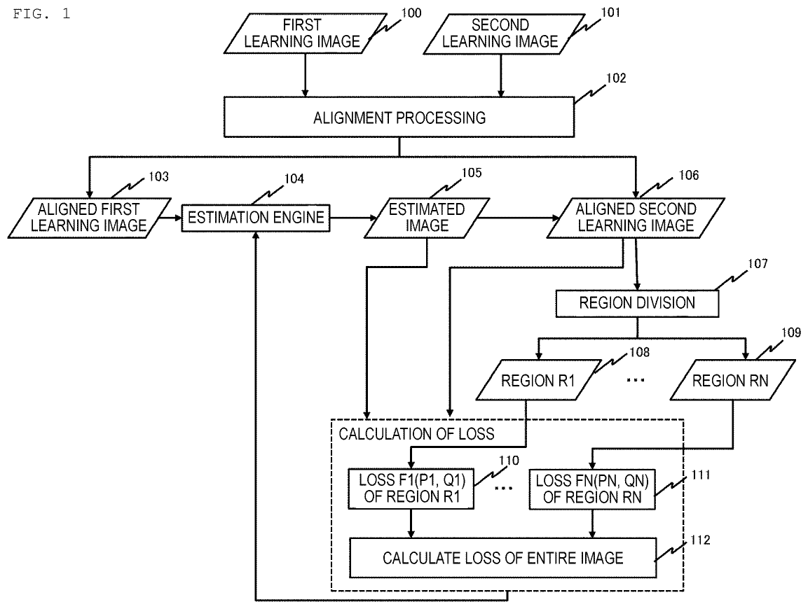

FIG. 1 illustrates an example of a learning processing sequence of the estimation engine according to the present embodiment. In the drawing, an image of a sample is captured, and a plurality of pairs of a first learning image (100) and a second learning image (101) are acquired.

Here, in a case of acquiring the first learning image and the second learning image, the first learning image and the second learning image are acquired such that the second learning image has higher quality than the first learning image by changing one or more conditions of the image resolution, the number of frames added, and the focus position. For example, as illustrated in FIG. 9, a first learning image (900) captured in a case where the number of frames added is 1 and a second learning image (901) captured in a case where the number of frames added is 64 may be used.

Next, the first learning image and the second learning image are aligned to acquire an aligned first learning image (103) and an aligned second learning image (106). In the alignment, normalized correlation, pixel difference, or the like is used as an evaluation value. The alignment may be performed on the basis of the position at which the evaluation value is maximum or minimum. In addition, in a case where the image resolutions of the first learning image and the second learning image are different, the alignment may be performed after adjusting the image resolutions through linear interpolation or the like before the alignment.

The aligned first learning image (103) is input to an estimation engine (104) to acquire an estimated image (105). Region division processing (107) is applied to the aligned second learning image (106) to acquire regions R1 (108) to RN (109). Then, a loss between a pixel group Pi of the aligned second learning image (106) and a pixel group Qi of the estimated image (105) is calculated using a different loss function Fi, for each region Ri (i=1 to N, where N is the number of regions).

That is, in the region R1, the loss is calculated using a loss function F1, and in the region RN, the loss is calculated using a loss function FN different from F1. The loss of the entire image is calculated (112) by adding up the losses (110, 111) for each region, and an estimation processing parameter of the estimation engine (104) is updated on the basis of the loss.

It should be noted that, as the estimation engine (104), various existing machine learning methods can be used. Examples of the methods include a deep neural network and the like.

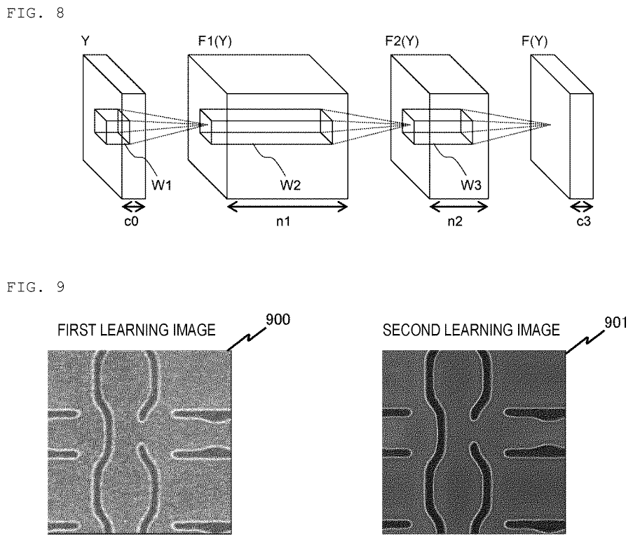

As a method using the deep neural network, a convolutional neural network described in NPL 1 may be used. Specifically, a neural network having a three-layer structure illustrated in FIG. 8 may be used. Here, Y indicates an input image, F1(Y) and F2(Y) indicate intermediate data, and F(Y) indicates an estimation result. It should be noted that the intermediate data and the estimation result are calculated through Expressions 1 to 3. “*” indicates a convolution operation. Here, W1 is n1 filters with sizes of c0×f1×f1. co indicates the number of channels of the input image, and f1 indicates a size of a spatial filter. An n1-dimensional feature map is obtained by performing convolution of the input image and the filter with the size of c0×f1×f1 n1 times. B1 is an n1-dimensional vector and a bias component corresponding to the n1 filters. Similarly, W2 is a filter with a size of n1×f2×f2, B2 is a n2-dimensional vector, W3 is a filter with a size of n2×f3×f3, and B3 is a c3-dimensional vector.

$$F 1 ( Y ) = max ( 0 , W 1 * Y + B 1 ) \qquad ( Expression 1 )$$

$$F 2 ( Y ) = max ( 0 , W 2 * F 1 ( Y ) + B 2 ) \qquad ( Expression 2 )$$

$$F ( Y ) = W 3 * F 2 ( Y ) + B 3 \qquad ( Expression 3 )$$

Among these values, c0 and c3 are values defined by the number of channels of the first learning image and the second learning image. Further, f1, f2, n1, and n2 are hyperparameters determined by a user before the learning sequence. For example, the hyperparameters may be f1=9, f2=5, n1=128, and n2=64. The parameters adjusted by the learning of the estimation engine (104) are W1, W2, W3, B1, B2, and B3.

It should be noted that there are various methods of region division for the purpose. Specific examples of the region division methods include the following.
(A1) Division into edge and non-edge regions
(A2) Division into upper and lower pattern regions
(A3) Division into defective and normal (non-defective) regions
(A4) Pre-labeling of the design data and label-based region division

In the present specification, the above-mentioned (A1) to (A4) are described as examples of region division, but the region division is not limited to the examples, and the regions can be divided in any manner on the basis of the application and designation of a user.

(2)

For a sample observation image, in edge regions such as the contours of circuit patterns, an image with a strong contrast and estimation of fine features are important. In contrast, in flat portions without unevenness (non-edge regions), an estimated image with a weak contrast and an estimated image, from which fine elements such as noise are removed, are important so as to not perform erroneous recognition with defects, circuit patterns, and the like.

Regarding this issue, in addition to the above-mentioned feature (1), the present embodiment further includes the following feature. In the region division processing (104), a luminance gradient image is acquired by applying a differential filter to the second learning image, and the estimated image corresponding to the first learning image and the second learning image are divided (A1) into an edge region R1 and a non-edge region R2 of the circuit pattern by using the luminance gradient image and an edge determination threshold, and the estimation processing parameters are learned using the loss function F1 for R1 and the loss function F2 for R2.

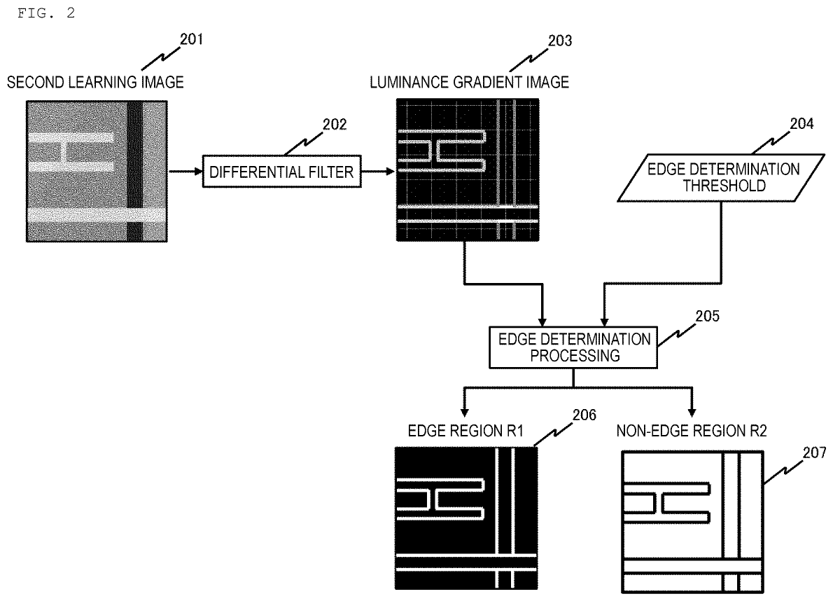

A supplementary description of these features will be given with reference to FIG. 2.

In the drawing, a luminance gradient image (203) is acquired by applying a differential filter (202) to a second learning image (201). Various methods can be used for the differential filter. For example, a sum of an absolute value of a difference between a target pixel and an adjacent pixel on the right side and an absolute value of a difference between the target pixel and an adjacent pixel on the lower side may be used as a differential filter result. Then, in the edge determination processing (205), the luminance gradient image (203) is binarized using the luminance gradient image (203) and an edge determination threshold (204), and is divided into an edge region R1 (206) and a non-edge region R2 (207). It should be noted that the edge determination threshold (204) may be set by a user or may be set in accordance with a predetermined rule. Due to the above features, learning is performed using different loss functions for the edge region and the non-edge region. Thus, it is possible to perform learning to estimate images with different image qualities for the edge region and the non-edge region.

(3)

In the sample observation image, in a case where the sample has a multi-layer circuit pattern, it may be necessary to estimate an image with a high contrast on a specific layer. Regarding this issue, in the present embodiment, in addition to the features described in (1) and (2), in the region division processing (107), the second learning image and the estimated image corresponding to the first learning image and the second learning image are divided into a region R1′ of the first layer pattern to a region RN′ of the Nth layer pattern by using the second learning image and a layer determination threshold, and the estimation processing parameter is learned using a loss function Fi′ for Ri′(i=1 to N, where N is the number of regions).

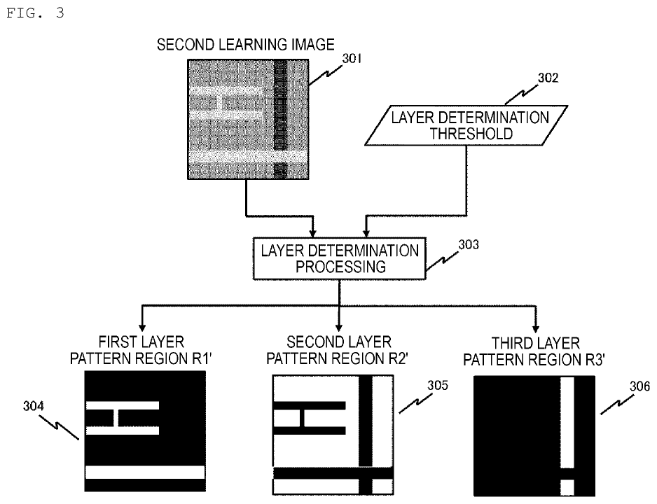

A supplementary description of this feature (3) will be given using an image with a three-layer circuit pattern illustrated in FIG. 3 as an example.

A second learning image (301) and a layer determination threshold (302) are input to a layer determination processing (303) to be divided into a first layer pattern region R1′ (304), a second layer pattern region R2′ (305), and a third layer pattern region R3′ (305).

For example, in a case where an image of a semiconductor wafer having a multi-layer circuit pattern is captured through a charged particle microscope, generally, it is possible to obtain an image in which the pattern on the upper layer is brighter and the pattern on the lower layer is darker. Therefore, in the layer determination processing, it is possible to separate a luminance of the second learning image (301) by converting the luminance into N values on the basis of the layer determination threshold (302). Due to this feature, it is possible to perform learning to estimate images with different image qualities depending on the layer, that is, images with high contrast for a specific layer, by performing the learning through different loss functions for the respective regions which are divided for each layer.

(4)

In the sample observation image, in a case where a defect is present in the sample, the visibility of the defective region is important, and the image with a high contrast of the defect may be necessary. Further, it is important to estimate an image with less noise such that a defect is not erroneously recognized in a non-defective region, and items considered important in image estimation may differ depending on whether a defect is present.

Regarding this issue, in addition to the features described above, the present embodiment further includes the following feature.

The first learning image and the second learning image are acquired on the basis of the defect coordinate information,

a reference image, which corresponds to the second learning image and does not contain any defects, is acquired,

a defective region in the second learning image is detected using the second learning image and the reference image,

an estimated image corresponding to the first learning image and the second learning image are divided into a defective region R1″ and a non-defective region R2″ on the basis of the detected region, and estimation processing parameters are learned using a loss function F1″ for R1″ and a loss function F2″ for R2″.

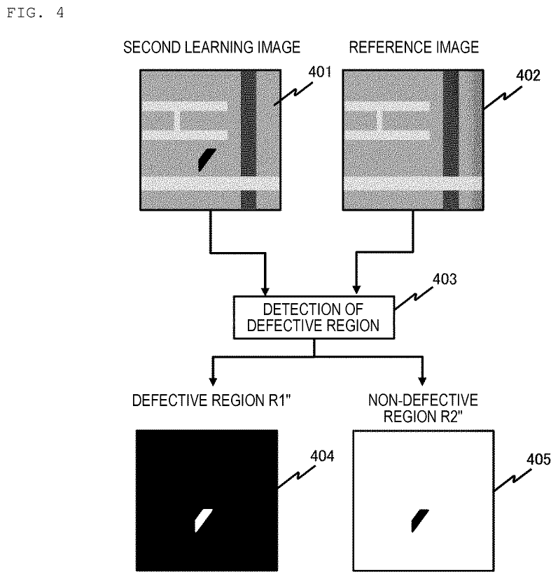

A supplementary description of this feature (4) will be given with reference to FIG. 4.

A second learning image (401) and an image of a region, in which a circuit pattern similar to the circuit pattern in the second learning image is formed, are captured to acquire a reference image (402). The second learning image is compared with the reference image to detect a defective region (403). Then, the second learning image is divided into the defective region R1″ (404) and the non-defective region R2″ (405).

According to this feature, it is possible to perform learning using different loss functions for the defective region R1″ and the non-defective region R2″. Thus, it is possible to perform learning to estimate an image with high visibility of the defect and low noise in the non-defective region.

(5)

In the sample observation image, it may be necessary to estimate an image with a high contrast within a specific pattern. Regarding this issue, in addition to the above-mentioned features, the embodiment of the invention further includes the following feature. The labels are assigned to the design data, either the first learning image or the second learning image is aligned in accordance with the design data, the second learning image is divided into regions Ri (i=1 to N, where N is the number of regions) on the basis of the alignment result and the labels, and estimation processing parameters are learned using loss functions Fi′″ for the regions Ri′″.

Here, the design data is layout data on the sample to be observed. For example, in a case where the sample is a semiconductor, the design data is data in which edge information of a design shape of a semiconductor circuit pattern is written as coordinate data.

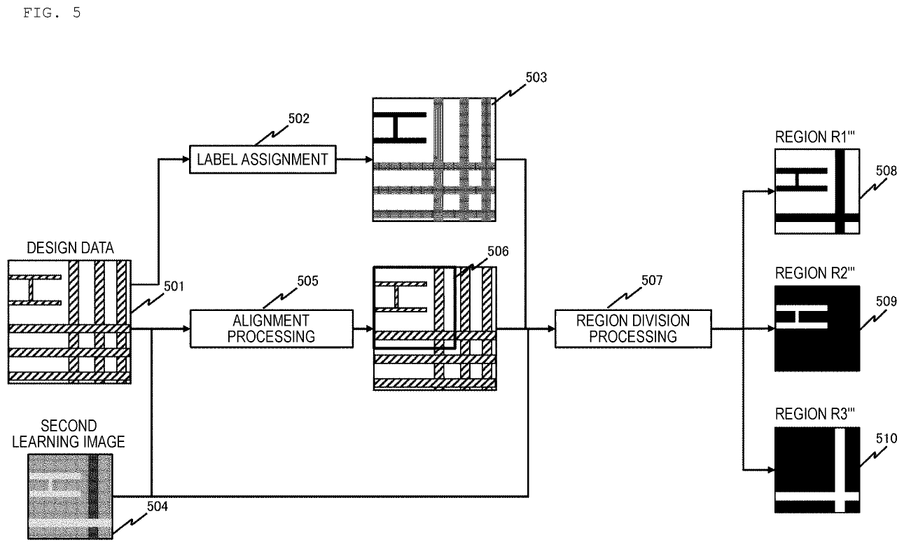

A supplementary description of this feature (5) will be given with reference to FIG. 5. Using layout information (501) acquired from the design data, labels are assigned to patterns and background portions (502), and a labeled image is acquired (503). In the example of FIG. 5, three types of labels are assigned. Further, design data (501) and a second learning image (504) are cross-checked to acquire a position (506) corresponding to the second learning image (505). Regions R1′″ to R3′″ (508 to 510) are acquired by performing region division processing (507) on the second learning image (504) on the basis of the design data (506) and the label image (503) corresponding to the second learning image.

In the processing of acquiring the corresponding position, for example, edges may be extracted from the second learning image to acquire contour information of the pattern, and searching may be performed at the corresponding position by comparing the contour information with the design data.

Due to this feature, by learning using a different loss function for each region corresponding to the label assigned to the design data, it is possible to perform learning to estimate an image with a high contrast of a specific pattern.

(6)

Image quality has various elements such as luminance and contrast, and it is difficult to express the image quality with a single loss function. Therefore, in the present embodiment, in addition to the feature described in (1), the loss function Fi is defined as a weighted sum of element losses calculated using a plurality of element loss functions fij (j=1 to M, M is the number of element losses), and a weight wij of an element loss value is changed for each region Ri of the second learning image.

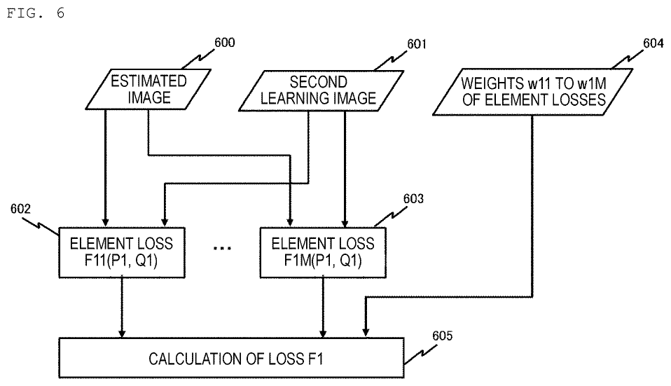

A supplementary description of this feature (6) will be given with reference to FIG. 6. It should be noted that the description will be given using a loss F1 (P1, Q1) as an example, but the description can be applied to any loss Fi (Pi, Qi).

An estimated image (600) and the second learning image are input, and element loss functions F11 to F1M (602 and 603) are calculated. Weights w11 to w1M (604) of element losses, each of which indicates which element loss is important, and the element losses (602 and 603) are input, and the loss F1 (P1, Q1) is calculated (605).

Here, the loss F1 (P1, Q1) is calculated as the weighted sum of the element losses illustrated in the following expression.

$$F 1 ( P 1 , Q 1 ) = w 11 f 11 ( P 1 , Q 1 ) + w 12 f 12 ( P 1 , Q 1 ) + … + w 1 Mf 1 M ( P 1 , Q 1 )$$

The element loss function is a method for calculating a loss (element loss) corresponding to each element with image quality. For example, in the loss function Fi, an element loss function relating to luminance is represented by an absolute square error (Pi−Qi)\hat{2}, and an element loss function relating to the contrast is represented by an absolute square error (Pi′−Qi′)\hat{2} of luminance gradients. It should be noted that Pi′ is a luminance gradient of the pixel group Pi, and Qi′ is a luminance gradient of the pixel group Qi.

Due to the above feature, by calculating and learning the weighted sum of a plurality of element losses calculated by a plurality of element loss functions for each region Ri, it is possible to perform learning to estimate an image in which a plurality of elements relating to image quality are reflected.

(7)

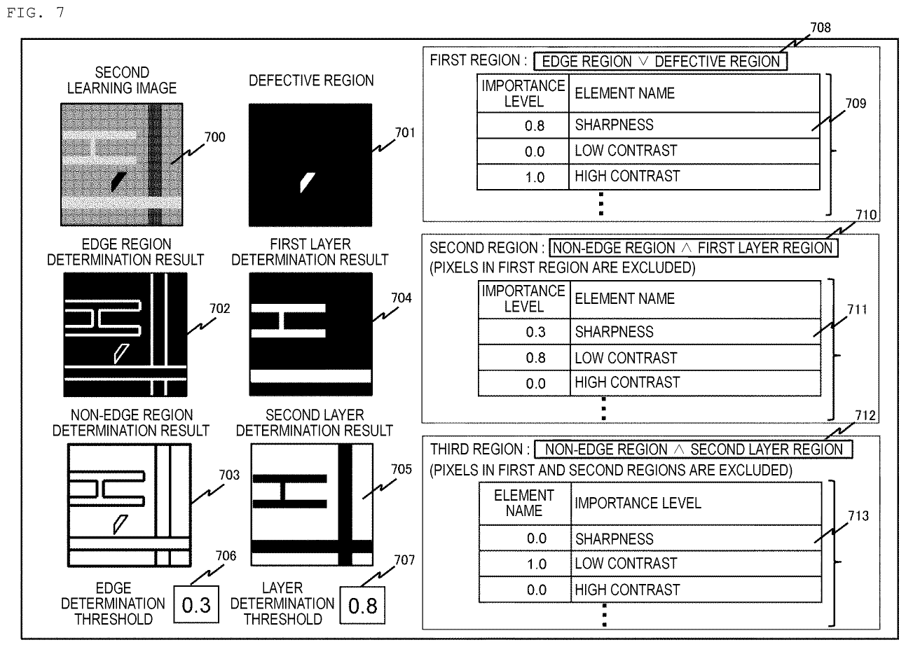

FIG. 7 illustrates an example of a graphical user interface (GUI) for implementing the present embodiment.

In this GUI, a determination threshold for region division can be set, and an importance level of each region can be designated.

Region division is performed on a second learning image (700), and a defective region (701), an edge region (702), a non-edge region (703), a first layer region (704), and a second layer region (705) are displayed. Further, thresholds used in region division can be set (706, 707). Furthermore, each region can be set (708, 710, 712), and the importance level of each element in each region can be set (709, 711, 713). The weight (604) of each element loss function can be set on the basis of the importance level which is set herein, and can be reflected in the loss.

The invention is not limited to the above-mentioned examples, and further includes various modification examples. For example, the above-mentioned embodiments and modification examples have been described in detail to make the invention easier to understand, and are not necessarily limited to those having all of the configurations described.

1. A sample observation method, comprising:
acquiring a first learning image and a second learning image corresponding to the first learning image,
learning an estimation processing parameter of an estimation engine that estimates the second learning image from the first learning image using the first learning image and the second learning image,
wherein, in learning of the estimation processing parameter, an estimated image, which is estimated from the first learning image, and the second learning image corresponding to the first learning image are divided into regions Ri (i=1 to N, where N is the number of regions), and
the learning is performed using a loss function Fi of evaluating a loss between a pixel group Pi of the second learning image and a pixel group Qi of the estimated image included in each region Ri on the basis of a predetermined criterion.

2. The sample observation method according to claim 1,
wherein, in a case of capturing the first learning image and the second learning image,
one or more of conditions of an image resolution, the number of frames added, and a focus position are changed, such that the second learning image has higher quality than the first learning image.

3. The sample observation method according to claim 2,
wherein the estimation engine uses a convolutional neural network, and
wherein the estimation processing parameter is updated through error back propagation processing such that the loss calculated by the loss function is reduced.

4. The sample observation method according to claim 3,
wherein a luminance gradient image is acquired by applying a differential filter to the second learning image, the estimated image, which is estimated from the first learning image, and the second learning image are divided into an edge region R1 and a non-edge region R2 of a circuit pattern by using the luminance gradient image and an edge determination threshold, and the estimation processing parameter is learned using a loss function F1 for the edge region R1 and a loss function F2 for the non-edge region R2.

5. The sample observation method and apparatus according to claim 3,
wherein the estimated image, which is estimated from the first learning image, and the second learning image are divided into a region R1′ of a first layer pattern to a region RN′ of an Nth layer pattern by using the second learning image and a layer determination threshold, and the estimation processing parameter is learned using a loss function Fi′ (i=1 to N, where N is the number of regions) for the region Ri′.

6. The sample observation method according to claim 3,
wherein the first learning image and the second learning image are acquired on the basis of defect coordinate information,
wherein a reference image corresponding to the second learning image and not including a defect is acquired, and
wherein a defective region in the second learning image is detected using the second learning image and the reference image, and the estimated image, which is estimated from the first learning image, and the second learning image are divided into a defective region R1″ and a non-defective region R2″ on the basis of the detected region, and the estimation processing parameter is learned using a loss function F1″ for the defective region R1″ and a loss function F2″ for the non-defective region R2″.

7. The sample observation method-and apparatus according to claim 3,
wherein a label is assigned to design data,
wherein either the first learning image or the second learning image is aligned in accordance with the design data,
wherein the second learning image is divided into regions Ri″ (i=1 to N, where N is the number of regions) on the basis of an alignment result and the label, and
wherein the estimation processing parameter is learned using a loss function Fi″ for a region Ri″.

8. The sample observation method according to claim 4,
wherein the loss function Fi is defined as a weighted sum of element losses calculated using a plurality of element loss functions fij (j=1 to M, where M is the number of element losses), and has a different weight for each region Ri of the second learning image.

9. The sample observation method according to claim 5,
wherein the loss function Fi is defined as a weighted sum of element losses calculated using a plurality of element loss functions fij (j=1 to M, where M is the number of element losses), and has a different weight for each region Ri of the second learning image.

10. The sample observation method according to claim 6,
wherein the loss function Fi is defined as a weighted sum of element losses calculated using a plurality of element loss functions fij (j=1 to M, where M is the number of element losses), and has a different weight for each region Ri of the second learning image.

11. The sample observation method according to claim 7,
wherein the loss function Fi is defined as a weighted sum of element losses calculated using a plurality of element loss functions fij (j=1 to M, where M is the number of element losses), and has a different weight for each region Ri of the second learning image.
